(19) United States
(12) Patent Application Publication
(10) Pub. No.: US 2008/0237833 A1
(43) Pub. Date: Oct. 2, 2008

(54) MULTI-CHIP SEMICONDUCTOR PACKAGE STRUCTURE

(75) Inventors: Shih-Ping Hsu, Hsin-Chu (TW); Chung-Cheng Lien, Hsin-Chu (TW); Chia-Wei Chang, Hsin-Chu (TW)

Correspondence Address: PEARNE & GORDON LLP, 1801 EAST 9TH STREET, SUITE 1200, CLEVELAND, OH, 44114-3108, US

(73) Assignee: PHOENIX PRECISION TECHNOLOGY CORPORATION, Hsin-Chu (TW)

(21) Appl. No.: 12/047,851

(22) Filed: Mar. 13, 2008

(30) Foreign Application Priority Data
Mar. 27, 2007 (TW) 096110456

(51) Int. Cl. H01L 23/49

(52) U.S. Cl. 257/691; 257/E23.024

(57) ABSTRACT

A multi-chip semiconductor package structure is disclosed according to the present invention. The package structure includes: a carrier board having a first surface, a second surface, and at least one opening penetrating the first and second surfaces, the first and second surfaces each being formed with a plurality of electrically connecting pads thereon; a semiconductor component received in the opening and having first and second active surfaces, the first and second active surfaces each being formed with a plurality of electrode pads thereon; a plurality of first conductive elements electrically connected to the electrically connecting pads on the second surface of the carrier board and the electrode pads on the second active surface of the semiconductor component; a semiconductor chip having an active surface and an inactive surface, the active surface having a plurality of electrode pads electrically connected to the electrically connecting pads on the first surface of the carrier board and the electrode pads on the first active surface of the semiconductor component; and a molding material formed on a portion of the second surface of the carrier board and the second active surface of the semiconductor component to cover the first conductive elements. The present invention provides a modularized structure capable of electrically connecting to other modules or stacked devices as well as enhancing electrical performance.

### BACKGROUND OF THE INVENTION

1. Field of the Invention

The present invention generally relates to a package structure, and more specifically, to a multi-chip semiconductor package structure.

2. Description of Related Art

Owing to the evolution of semiconductor package technologies, a great variety of packaging models of semiconductor devices have been developed. A traditional semiconductor device mainly has a package substrate or a lead frame, thereon a semiconductor component, such as an integrated circuit, is mounted, and then the semiconductor component is electrically connected to the package substrate or the lead frame before proceeding to an encapsulation process with encapsulant. To fit in with the trend of miniaturization, high memory storage capacity, and high speed of electronic products by increasing electricity functions of semiconductor components and fulfilling the goal of high integration and miniaturization of semiconductor packages as well as enhancing the performance and memory storage capacity of a single semiconductor package, most known semiconductor packages have multiple chips packaged by multi chip module (MCM). The MCM packages are characterized by reduced overall volume and enhanced electricity functions and thus have become mainstream packages, wherein at least two semiconductor chips are mounted on a chip carrier of a single package, and each of the semiconductor chips is mounted on the carrier by being stacked up; this sort of packaging structure of stacked chips has been disclosed in U.S. Pat. No. 6,798,049.

As shown in FIG. 1, which is a cross-sectional view of a semiconductor package according to U.S. Pat. No. 6,798,049, the essential features disclosed in U.S. Pat. No. 6,798,049 are: an opening 101 formed in a circuit board 10; a circuit layer 11, which has electrically connecting pads 11a and wire bonding pads 11b, is formed on at least one surface of the circuit board 10; two semiconductor chips 121 and 122 stacked and integrated together inside the opening 101, wherein the two semiconductor chips 121 and 122 are electrically connected to each other with a bonding layer 13 in between; the semiconductor chip 122 is electrically connected to the wire bonding pads 11b on the circuit layer 11 via conductive elements 14, such as gold wires, and then the opening 101 of the circuit board 10 is filled with encapsulant 15 to encapsulate the semiconductor chips 121 and 122 as well as the conductive elements 14; a solder mask 16 is formed on the circuit layer 11 of the circuit board 10, and then a plurality of openings 16a are formed in the solder mask 16 to expose the electrically connecting pads 11a, and also a conductive element 17, such as a solder ball, is formed on each opening 16a of the solder mask 16; a packaging process is completed thus.

However, the two semiconductor chips 121 and 122 require the bonding layer 13 of chip scale connection in between to electrically connect to each other. In other words, the semiconductor chips 121 and 122 need a pre-stacking process of electrical connection in a chip fabrication plant before being delivered to a packaging plant for packaging, thus the fabrication process is more complicated, and in consequence the production cost is high.

In the case of a chip stacking process intended for enhancement of electricity functions and multi chip module performance, additional enhancement requires additional stacking which, however, increases complexity of the circuit layer 11, not to mention that the amount of wire bonding pads 11b of the circuit layer 11 must be increased. To increase the amount of wire bonding pads 11b and circuit density in a limited or fixed usable area, the circuit board for carrying the semiconductor chips 121 and 122 must have fine lines in order to meet the requirement for compact packages.

However, fine circuit lines have a limited effect on reducing required circuit board area. In the case of directly stacking up semiconductor chips 121 and 122 for increasing electrical functions and multi-chip module performances, electrical functions and multi-chip module performances cannot be continuously expanded because the amount of stackable chips is limited.

Hence, the circuit board manufacturing sector is faced with an urgent issue that involves providing a package structure capable of effectively increasing density of multi-chip modules mounted on a circuit board of multi-layers, decreasing the required area on the circuit board of multi-layers for mounting semiconductor chips, achieving the goal to reduce package size, and consequently enhancing memory storage capacity.

### SUMMARY OF THE INVENTION

In view of the disadvantages of the prior art mentioned above, it is a primary objective of the present invention to provide a multi-chip semiconductor package structure capable of stacking up multiple chips as well as enhancing electrical performance of the package structure.

It is another objective of the present invention to provide a multi-chip semiconductor package structure capable of simplifying a fabrication process as well as reducing cost.

It is a further objective of the present invention to provide a multi-chip semiconductor package structure capable of stacking up with other electronic devices, as well as enhancing and expanding electrical functions.

To achieve the aforementioned and other objectives, a multi-chip semiconductor package structure is provided according to the present invention. The multi-chip semiconductor package structure comprises: a carrier board having a first surface, a second surface, and at least one opening penetrating the first and second surfaces, the first and second surfaces being formed with a plurality of electrically connecting pads thereon; a semiconductor component received in the opening and having first and second active surfaces, the first and second active surfaces each being formed with a plurality of electrode pads thereon; a plurality of first conductive elements electrically connected to the electrically connecting pads on the second surface of the carrier board and the electrode pads on the second active surface of the semiconductor component; a semiconductor chip having active and inactive surfaces, and the active surface has a plurality of electrode pads electrically connected to the electrically connecting pads on the first surface of the carrier board and the electrode pads on the first active surface of each semiconductor component; and a molding material formed on a portion of the second surface of the carrier board and the second active surface of the semiconductor component to cover the first conductive elements.

The carrier board comprises one of a single circuit board and a plurality of circuit boards. The first conductive elements are metal conducting wires.

The semiconductor component comprises first and second semiconductor chips, and each of the first and second semiconductor chips has an active surface and an inactive surface. The active surfaces are formed with a plurality of electrode pads thereon. The first and second semiconductor chips are integrated with one another by face-to-face coupling of the inactive surfaces thereof. The active surfaces of the first and second semiconductor chips are exposed so as to become the first active surface and the second active surface of the semiconductor component. The multi-chip semiconductor package structure further comprises a bonding material formed on the inactive surfaces of the first and second semiconductor chips so as to integrate the first and second semiconductor chips with one another. The bonding material is made of UV (Ultra Violet) paste or epoxy resin. The semiconductor component is fixed inside the opening with an adhesive.

The multi-chip semiconductor package structure of the present invention further comprises a plurality of second conductive elements implemented as solder balls and formed between the electrically connecting pads on the first surface of the carrier board and the electrode pads of the semiconductor chip for electrically connecting the carrier board to the semiconductor chip, as well as between the electrode pads on the first active surface of the semiconductor component and the electrode pads of the semiconductor chip for electrically connecting the carrier board, the semiconductor component, and the semiconductor chip.

A plurality of third conductive elements are formed on a portion of the electrically connecting pads on the first surface of the carrier board, wherein the portion of the electrically connecting pads are not electrically connected to the semiconductor chip. The third conductive elements are solder balls, pins, or metal pads.

The multi-chip semiconductor package structure of the present invention further comprises a stacked device electrically connected, via a plurality of fourth conductive elements, to the electrically connecting pads formed on the second surface of the carrier board but not covered with the molding material. The stacked device is one selected from the group consisting of a flip chip package structure, a wire bond package structure, and a chip-embedded package structure.

In view of the aforementioned descriptions, the multi-chip semiconductor package structure of the present invention has the following features: integrate the first and second semiconductor chips with one another by face-to-face coupling of inactive surfaces thereof so as to become a semiconductor component; receive the semiconductor component having first and second semiconductor chips in an opening of the carrier board; and then have the first conductive elements and the semiconductor chip electrically connected to the carrier board, thereby enhancing electrical performance as well as avoiding problems of high cost and complexity of stacking chips and electricity connections found in prior art; the molding material and the semiconductor component are boned together effectively, thereby enhancing reliability. Besides, the carrier board embedded with semiconductor components is capable of stacking up with and electrically connected to stacked devices, thereby enhancing and expanding electrical functions.

### BRIEF DESCRIPTION OF DRAWINGS

The present invention can be more fully understood by reading the following detailed description of the preferred embodiments, with reference made to the accompanying drawings, wherein:

FIG. 1 is a cross-sectional view of a semiconductor package according to U.S. Pat. No. 6,798,049;

FIGS. 2A through 2G are cross-sectional views of a fabrication method of a multi-chip semiconductor package structure of the present invention; and

FIG. 3 is a cross-sectional view showing a package structure being stacked on a multi-chip semiconductor package structure of the present invention.

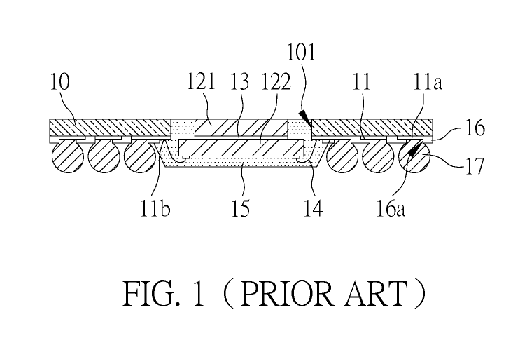

### DETAILED DESCRIPTION OF PREFERRED EMBODIMENTS

The following illustrative embodiments are provided to illustrate the disclosure of the present invention, these and other advantages and effects can be apparently understood by persons skilled in the art after reading the disclosure of the specification. The present invention can also be performed or applied by other different embodiments. The details of the specification may be modified on the basis of different points and applications, and numerous modifications and variations can be devised without departing from the spirit of the present invention.

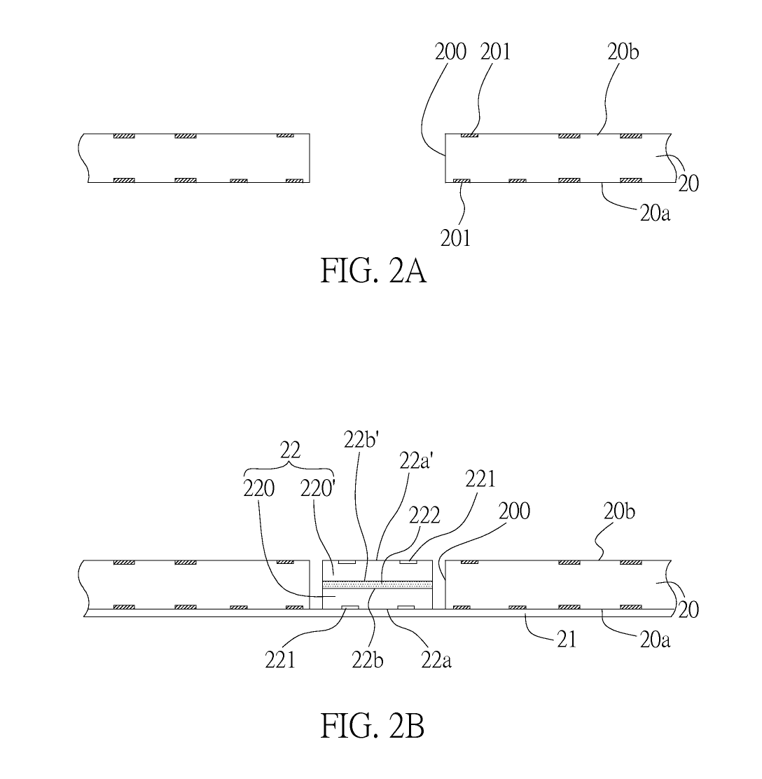

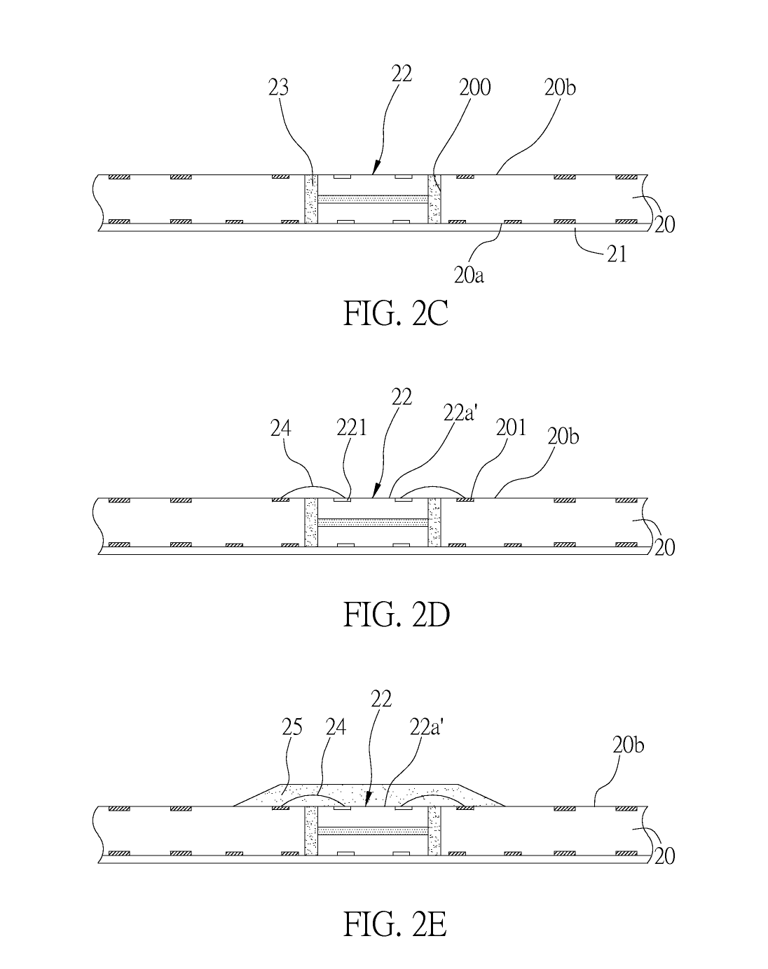

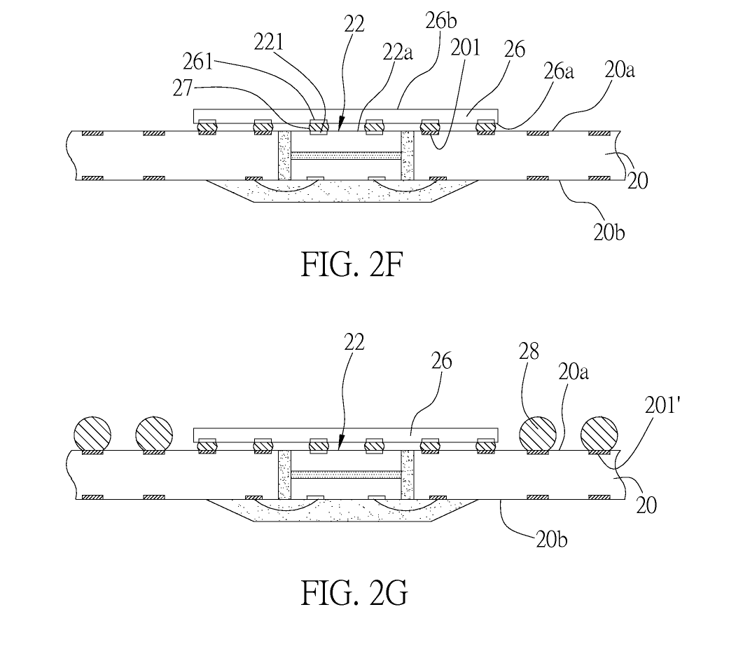

Please refer to FIGS. 2A through 2G, which are cross-sectional views of a fabrication method of a multi-chip semiconductor package structure of the present invention.

As shown in FIG. 2A, a carrier board 20 comprising a single circuit board or a plurality of circuit boards is provided. The carrier board 20 has a first surface 20a, a second surface 20b, and at least one opening 200 penetrating the first surface 20a and the second surface 20b. The first surface 20a and the second surface 20b of the carrier board 20 are formed with a plurality of electrically connecting pads 201 thereon.

As shown in FIG. 2B, a de-molding film 21 is formed on the first surface 20a of the carrier board 20 to seal one end of the opening 200, and then a semiconductor component 22 is mounted on the surface of the de-molding film 21 inside the opening 200. The semiconductor component 22 has a first active surface 22a and a second active surface 22a′. The first active surface 22a and the second active surface 22a′ are each formed with a plurality of electrode pads 221 thereon. The semiconductor component comprises first and second semiconductor chips 220 and 220′. The first semiconductor chip 220 has an active surface 22a and an inactive surface 22b, and the second semiconductor chip 220′ has an active surface 22a′ and an inactive surface 22b′. The active surfaces 22a and 22a′ are formed with a plurality of electrode pads 221 thereon. A bonding material 222 is formed between the inactive surfaces 22b and 22b′ of the first and second semiconductor chips 220 and 220′, such that the first and second semiconductor chips 220 and 220′ are bonded together so as to become a semiconductor component 22, wherein the active surfaces 22a and 22a′ of the first and second semiconductor chips 220 and 220′ are exposed so as to become the first and second active surfaces 22a and 22a′ of the semiconductor component 22. The bonding material is made of either UV paste or epoxy resin.

The first and second semiconductor chips 220, 220′ can be bonded together by the bonding material 222 after the wafers respectively comprising the first and second semiconductor chips 220, 220′ are singulated. Alternatively, the wafers respectively comprising the first and second semiconductor chips 220, 220′ can be bonded together by the bonding material 222 first and then singulated to form the semiconductor component 22.

As shown in FIG. 2C, an adhesive 23 is formed in a gap between the opening 200 of the carrier board 20 and the semiconductor component 22 to fix the semiconductor component 22 inside the opening 200.

As shown in FIG. 2D, first conductive elements 24, e.g. metal conducting wires, are electrically connected to the electrically connecting pads 201 on the second surface 20b of the carrier board 20 and the electrode pads 221 on the second active surface 22a′ of the semiconductor component 22.

As shown in FIG. 2E, a molding material 25 is formed on the second active surface 22a′ of the semiconductor component 22 and a portion of the second surface 20b of the carrier board 20 to cover the first conductive elements 24, and consequently encapsulate the semiconductor component 22 inside the opening 200 of the carrier board 20.

As shown in FIG. 2F, the carrier board 20 is turned over to have the first surface 20a of the carrier board 20 face upward, and then the de-molding film 21 is removed to expose the electrically connecting pads 201 on the first surface 20a of the carrier board 20 and the electrode pads 221 on the first active surface 22a of the semiconductor component 22.

Next, have a third semiconductor chip 26 electrically connected to the carrier board 20 and the semiconductor component 22. The third semiconductor chip 26 has an active surface 26a and an inactive surface 26b. The active surface 26a has a plurality of electrode pads 261. The electrode pads 261 are electrically connected to the electrically connecting pads 201 on the first surface 20a of the carrier board 20 and the electrode pads 221 on the first active surface 22a of the semiconductor component 22 via a plurality of second conductive elements 27 implemented as solder balls.

As shown in FIG. 2G, a plurality of third conductive elements 28 are formed on a portion of the electrically connecting pads 201′ on the first surface 20a of the carrier board 20, wherein the portion of the electrically connecting pads 201′ are not electrically connected to the third semiconductor chip 26. The third conductive elements 28 are solder balls, pins, or metal pads, and are adapted for electrical connection with other electronic devices to complete fabrication of the multi-chip semiconductor package structure of the present invention.

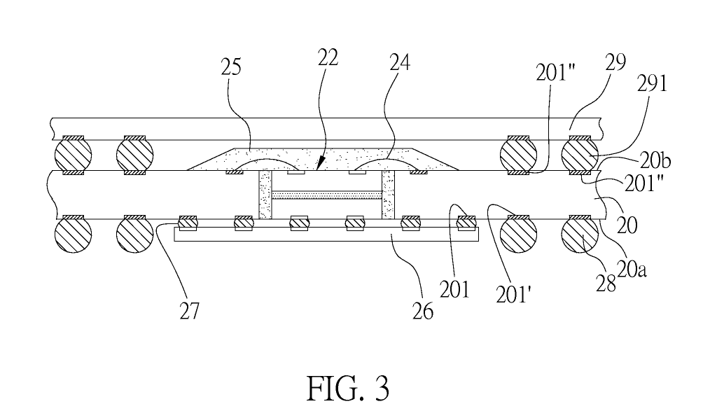

Please refer to FIG. 3, which is a cross-sectional view illustrating stacking up a stacked structure on the abovementioned multi-chip semiconductor package structure of FIG. 2G. As shown in the drawing, a portion of the electrically connecting pads 201″ on the second surface 20b of the carrier board 20 are not covered by the molding material 25, and a stacked device 29 is electrically connected to the portion of the electrically connecting pads 201″ via a plurality of fourth conductive elements 291. The stacked device 29 is one selected from the group consisting of a flip chip package structure, a wire bond package structure, and a chip-embedded package structure, thereby enhancing electrical performance of the carrier board 20 embedded with the semiconductor component 22.

In view of the above, a multi-chip semiconductor package structure is disclosed according to the present invention; the multi-chip semiconductor package structure comprises: a carrier board 20 having a first surface 20a, a second surface 20b, and at least one opening 200 penetrating the first surface 20a and the second surface 20b, the first and second surfaces 20a and 20b of the carrier board 20 are formed with a plurality of electrically connecting pads 201 thereon; a semiconductor component 22 received in the opening 200 and having a first active surface 22a and a second active surface 22a′, the first and second active surfaces 22a and 22a′ each being formed with a plurality of electrode pads 221 thereon; a third semiconductor chip 26 having an active surface 26a and an inactive surface 26b, the active surface 26a being formed with a plurality of electrode pads 261 thereon, and the electrode pads 26a being electrically connected to the electrically connecting pads 201 on the first surface 20a of the carrier board 20 and the electrode pads 221 on the first active surface 22a of the semiconductor component 22; a plurality of first conductive elements 24 electrically connected to the electrically connecting pads 201 on the second surface 20b of the carrier board 20 and the electrode pads 221 on the second active surface 22a′ of the semiconductor component 22; and a molding material 25 formed on a portion of the second surface 20b of the carrier board 20 and the second active surface 22a′ of the semiconductor component 22 to cover the first conductive elements 24.

The carrier board 20 comprises either a single circuit board or a plurality of circuit boards. The first conductive elements 24 are metal conducting wires. The semiconductor component 22 is fixed inside the opening 200 of the carrier board 20 with the adhesive 23.

The semiconductor component 22 comprises first and second semiconductor chips 220 and 220′. The first semiconductor chip 220 has an active surface 22a and an inactive surface 22b, and the second semiconductor chip 220′ has an active surface 22a′ and an inactive surface 22b′. The inactive surfaces 22b and 22b′ are formed with a plurality of electrode pads 221 thereon. The first and second semiconductor chips 220 and 220′ are integrated with one another by face-to-face coupling of the inactive surfaces 22b and 22b′ thereof, using a bonding material 222. The active surfaces 22a and 22a′ are exposed so as to become the first active surface 22a and the second active surface 22a′ of the semiconductor component 22 respectively. The bonding material 222 is either UV paste or epoxy resin.

The electrode pads 261 on the active surface 26a of the third semiconductor chip 26 are electrically connected to the electrically connecting pads 201 on the first surface 20a of the carrier board 20 and the electrode pads 221 on the first active surface 22a of the semiconductor component 22 via a plurality of second conductive elements 27 implemented as solder balls.

A plurality of third conductive elements 28 are formed on a portion of the electrically connecting pads 201′ on the first surface 20a of the carrier board 20, wherein the portion of the electrically connecting pads 201′ are not electrically connected to the third semiconductor chip 26. The third conductive elements 28 are solder balls, pins, or metal pads. A portion of the electrically connecting pads 201″ on the second surface 20b of the carrier board 20 are electrically connected to a stacked device 29 via a plurality of fourth conductive elements 291, wherein the portion of the electrically connecting pads 201″ are not covered with the molding material 25. The carrier board 20 embedded with the semiconductor component 22 is capable of stacking up with and electrically connecting to the stacked device 29. The stacked device 29 is one selected from the group consisting of a flip chip package structure, a wire bond package structure, and a chip-embedded package structure.

The multi-chip semiconductor package structure of the present invention comprises a semiconductor component comprising a first semiconductor chip and a second semiconductor chip, wherein the first and second semiconductor chips are integrated with one another by face-to-face coupling of inactive surfaces thereof so as to become the semiconductor component, and thus the semiconductor component has a first active surface and a second active surface. Afterward, the semiconductor component having the first and second active surfaces is received in an opening of the carrier board and electrically connected to the carrier board, thereby enhancing electrical performance and avoiding problems of complexity and high cost of chip stacking and electricity connection as found in prior art. A molding material and the semiconductor component are effectively bonded together, thereby increasing reliability of products. Besides, the carrier board embedded with the semiconductor component is capable of stacking up with and electrically connecting to stacked devices, thereby being capable of expanding and enhancing electrical functions.

The foregoing descriptions of the detailed embodiments are only illustrative in order to disclose the features and functions of the present invention, but are not restrictive of the scope of the present invention. Persons skilled in the art should understand that any modifications and variations made according to the spirit and principle of the disclosure of the present invention should fall within the scope of the appended claims.

What is claimed is:

1. A multi-chip semiconductor package structure, comprising:
a carrier board having a first surface, a second surface, and at least one opening penetrating the first surface and the second surface, wherein the first and second surfaces of the carrier board are formed with a plurality of electrically connecting pads thereon;
a semiconductor component received in the opening and having a first active surface and a second active surface, the first and second active surfaces each being formed with a plurality of electrode pads thereon;
a plurality of first conductive elements electrically connected to the electrically connecting pads on the second surface of the carrier board and the electrode pads on the second active surface of the semiconductor component;
a semiconductor chip having an active surface and an inactive surface, the active surface having a plurality of electrode pads for the electrode pads to be electrically connected to the electrically connecting pads on the first surface of the carrier board and the electrode pads on the first active surface of the semiconductor component; and
a molding material formed on a portion of the second surface of the carrier board and the second active surface of the semiconductor component to cover the first conductive elements.

2. The multi-chip semiconductor package structure of claim 1, wherein the carrier board comprises one of a single circuit board and a plurality of circuit boards.

3. The multi-chip semiconductor package structure of claim 1, wherein the semiconductor component comprises a first semiconductor chip and a second semiconductor chip, the first and second semiconductor chips each having an active surface and an inactive surface, the active surfaces each having a plurality of electrode pads, the first and second semiconductor chips being integrated with one another by face-to-face coupling of the inactive surfaces thereof, such that the active surfaces are exposed so as to become the first and second active surfaces respectively.

4. The multi-chip semiconductor package structure of claim 3, further comprising a bonding material formed on the inactive surfaces of the first and second semiconductor chips, such that the first and second semiconductor chips are bonded together so as to become a semiconductor component.

5. The multi-chip semiconductor package structure of claim 4, wherein the bonding material is one of UV (Ultra Violet) paste and epoxy resin.

6. The multi-chip semiconductor package structure of claim 1, wherein the semiconductor component is fixed inside the opening with an adhesive.

7. The multi-chip semiconductor package structure of claim 1, further comprising a plurality of second conductive elements formed between the electrically connecting pads of the carrier board and the electrode pads of the semiconductor chip for electrically connecting the carrier board to the semiconductor chip, and between the electrode pads of the semiconductor component and the electrode pads of the semiconductor chip for electrically connecting the semiconductor component to the semiconductor chip.

8. The multi-chip semiconductor package structure of claim 7, wherein the second conductive elements are solder balls.

9. The multi-chip semiconductor package structure of claim 1, wherein the first conductive elements are metal conducting wires.

10. The multi-chip semiconductor package structure of claim 1, wherein a plurality of third conductive elements are formed on a portion of the electrically connecting pads on the first surface of the carrier board, wherein the portion of the electrically connecting pads are not electrically connected to the semiconductor chip.

11. The multi-chip semiconductor package structure of claim 10, wherein the third conductive elements are one selected from the group consisting of solder balls, pins, and metal pads.

12. The multi-chip semiconductor package structure of claim 1, wherein a portion of the electrically connecting pads on the second surface of the carrier board are not covered with the molding material.

13. The multi-chip semiconductor package structure of claim 12, further comprising a stacked device electrically connected, via a plurality of fourth conductive elements, to the electrically connecting pads on the second surface of the carrier board, wherein the electrically connecting pads are not covered with the molding material.

14. The multi-chip semiconductor package structure of claim 13, wherein the stacked device is one selected from the group consisting of a flip chip package structure, a wire bond package structure, and a chip-embedded package structure.
